(19) United States
(12) Patent Application Publication
(10) Pub. No.: US 2017/0219667 A1
(43) Pub. Date: Aug. 3, 2017

(54) Planar Standing Wave Trap for a Magnetic Resonance Tomograph

(71) Applicants: Andreas Fackelmeier, Thalmässing (DE); Klaus Huber, Effeltrich (DE); Sebastian Martius, Forchheim (DE); Ralph Oppelt, Uttenreuth (DE); Markus Vester, Nürnberg (DE)

(72) Inventors: Andreas Fackelmeier, Thalmässing (DE); Klaus Huber, Effeltrich (DE); Sebastian Martius, Forchheim (DE); Ralph Oppelt, Uttenreuth (DE); Markus Vester, Nürnberg (DE)

(21) Appl. No.: 15/422,136

(22) Filed: Feb. 1, 2017

(30) Foreign Application Priority Data
Feb. 1, 2016 (DE) 102016201441.2

(51) Int. Cl. G01R 33/36; G01R 33/30

(52) U.S. Cl. CPC G01R 33/3685; G01R 33/30

(57) ABSTRACT

A line with a standing wave trap for a magnetic resonance tomograph, and a patient couch and a magnetic resonance tomograph with the line are provided. The line includes a carrier material, a first conductor track that extends along the carrier material in the carrier material or on the carrier material, and a first conductor loop. The first conductor loop is arranged on or in the carrier material. The first conductor loop has a signal coupling to the first conductor track. The first conductor loop has a first interruption that is bridged with a first capacitance.

This application claims the benefit of DE 10 2016 201 441.2, filed on Feb. 1, 2016, which is hereby incorporated by reference in its entirety.

### BACKGROUND

The present embodiments relate to a standing wave trap.

Magnetic resonance tomographs are imaging devices that, for mapping an examination object, align nuclear spins of the examination object with a strong external magnetic field and excite the examination object by a magnetic alternating field for precession around this alignment. The precession or return of the spin from this excited state into a state with lower energy creates a magnetic alternating field as a response (e.g., a magnetic resonance signal) that is received via antennas.

With the aid of magnetic gradient fields, a spatial encoding, which subsequently makes it possible to assign the received signal to a volume element, is applied to the signals. The received signal is then evaluated, and a three-dimensional imaging representation of the examination object is provided.

To excite the precession of the spins, magnetic alternating fields with a frequency that corresponds to the Larmor frequency at the respective static magnetic field strength and very high field strengths or powers are to be provided. To improve the signal-to-noise ratio of the magnetic resonance signal received by the antennas, antennas (e.g., local coils) that are connected via electrically-conductive cables to the magnetic resonance tomograph are used. Through high field strengths, the magnetic alternating field for excitation induces significant currents in cables that, with the associated voltages, may also be a danger to the patient and to the electronics. If the cables concerned are screened cables with a sheath made of wire mesh, as coaxial cables, for example, then these induced currents will also be referred to as sheath currents that propagate as guided electromagnetic waves along the cable, or, with reflexions, may also form standing waves.

In order to prevent the propagation of these waves, interruptions in the cable may be provided. These interruptions may only be effective at the frequency of the magnetic alternating field, so that other currents (e.g., low-frequency currents) may propagate without hindrance. Therefore, frequency-selective blocking filters are used for interruption. The frequency-selective blocking filters may have an impedance that is as high as possible at the frequency of the magnetic alternating field. These blocking filters are also referred to as standing wave traps. In this way, the cable may be segmented by the standing wave traps arranged at regular intervals, so that no dangerous voltages may build up in the individual segments. In such cases, the distances are to be small compared to the wavelength of an electromagnetic wave with the frequency of the excitation field.

The large number of standing wave traps that are to be fitted provides that not insignificant costs arise for a magnetic resonance tomograph.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a low-cost standing wave trap is provided.

A line of one or more of the present embodiments with a standing wave trap for a magnetic resonance tomograph has a carrier material, a first conductor track that extends along the carrier material in the carrier material or on the carrier material, and a first conductor loop that is arranged in or on the carrier material. Any given insulators may be provided as carrier material in this case. In one embodiment, the carrier material exhibits a low attenuation for signals on the first conductor track, for example, by a small dielectricity constant.

The first conductor loop has a signal coupling to the first conductor track, where the first conductor loop has a first interruption that is bridged by a first capacitance.

A conductor loop is to be seen in this case as a form of a conductor that is homeomorphic to a torus, where the conductor loop is interrupted at at least one or also at a number of points in order to arrange a first capacitance in the conductor loop or, for example, also a further component such as an inductance or capacitance in the conductor loop.

The signal coupling of the conductor loop with the first conductor track may be ohmic or galvanic or also inductive and/or capacitive. In such cases, the first conductor track may be a signal line but also a ground line with a reference potential.

The conductor loop to may form a resonant circuit that may be tuned by a suitable dimensioning of the component and may be coupled for signaling to the first conductor track, so that, for example, an electromagnetic wave propagating on the first conductor track is attenuated and/or hindered in propagation.

A patient couch of one or more of the present embodiments for a magnetic resonance tomograph includes the inventive line.

With a patient couch, the line may be arranged in the interior of the patient couch. The line may then be embodied over an entire length as a rigid or flexible circuit, may also have a number of conductor loops, and may be manufactured at low cost by machine-based methods for circuit board fabrication and component placement.

The magnetic resonance tomograph of one or more of the present embodiments also features a line with standing wave trap, for example, in a patient couch or in other areas such as the receiving area for the patient, which are subjected to the radio-frequency excitation pulses. The magnetic resonance tomograph shares the advantages of the line and patient couch.

In an embodiment of the line, the carrier material is a circuit board.

In this case, a circuit board or a flexible circuit board made from a non-conductive material may be provided as carrier material, for example. The conductor track and/or the conductor loop may then be arranged on a surface or also inside the board (e.g., between two layers of the carrier material). A multi-layer circuit board also makes it possible for the first conductor track and one or more conductor loops to overlap.

A circuit board may be manufactured by machine in a simple and low-cost manner.

In an embodiment of the line, the first conductor loop is in ohmic contact in a coupling area with the first conductor track. In one embodiment, the first conductor loop may be electrically connected to the first conductor track via a bridge or a coupling resistor. In one embodiment, the first conductor loop is manufactured in one piece with the first conductor track (e.g., in a production step of the circuit board) from a common planar conductor layer.

The ohmic coupling is a simple and low-cost option for coupling the first conductor loop to the first conductor track.

In one embodiment of the line, the first conductor loop is routed over a predetermined distance in a coupling area spaced a short distance away from the first conductor track, so that the signal coupling is achieved, for example, in an inductive and/or capacitive manner.

A short distance away in this case may be a distance at which an electric and/or magnetic field of the first conductor still interacts with the conductor loop. The distance may amount to, for example, 5, 1, 0.1 or fewer percent of the wavelength of a signal with Larmor frequency on the first conductor track. Distances of 50 mm, 10 mm, 2 mm, 1 mm, 0.2 mm or less may be provided. The predetermined distance may amount to 10 mm, 50 mm, 100 mm, 200 mm or more, for example.

The spacing and the predetermined distance make it possible to set the coupling and the effectiveness of the standing wave trap suitably.

In an embodiment of the line, the carrier material also has one or more second conductor tracks. The one or more second conductor tracks have a signal coupling to the first conductor loop.

The line is capable of providing a standing wave trap for a number of first and second conductor tracks at the same time.

In one embodiment of the line, the first conductor loop has a slot in the coupling area. The slot does not interrupt the first conductor loop. This may be understood as the slot not running over the entire width or length of the line, but an ohmic connection still exists between the line on both sides of the slot. A number of slots may also be provided in the coupling area, for example, to subdivide a larger continuous conductor surface.

The slot reduces the size of contiguous conductor surfaces, so that losses through eddy currents induced in the surfaces may be reduced.

In an embodiment of the line, the first conductor loop has a bridging capacitance that short circuits the slot for high frequencies. The bridging capacitance may, for example, if the slot is open at one end, be arranged at this end of the slot. A number of bridging capacitances that are arranged along a slot and short circuit the slot at a number of points may also be provided.

The bridging capacitance has a frequency-dependent impedance, so that the bridging capacitance short circuits the interruption of the line by the slot for higher frequencies (e.g., the Larmor frequency), while for lower frequencies, eddy currents are suppressed by the interruption of the line by the slot.

In one form of embodiment, the standing wave trap of the line features a second conductor loop. The second conductor loop is coupled for signaling to the first conductor track. The carrier material of the line has a planar form that is divided by the conductor track into a first subsurface and a second subsurface that do not overlap. In other words, the first subsurface and the second subsurface are arranged next to one another or are arranged on or in the planar carrier material. The first conductor loop essentially extends into the first subarea, and the second conductor loop essentially extends into the second subarea. To essentially extend into a subarea may be understood as only a small part of the surface of a conductor loop (e.g., 1, 5, 10 or 20 percent of the surface of a conductor loop) extending into the other subarea. In one embodiment, the first conductor loop and the second conductor loop are adjacent or opposite one another on both sides of the first conductor track. In this case, the surfaces may be arranged symmetrically to the first conductor track. In one embodiment, the surfaces of the first conductor loop and of the second conductor loop are essentially the same size (e.g., the surface content of the first conductor loop and of the second conductor loop deviate from one another by less than 1, 5, 10 or 20 percent of the total surface of a conductor loop).

In one embodiment, the second conductor loop, the first conductor track, and/or the second conductor loop may be in ohmic contact with one another. The first conductor loop, the second conductor loop, and the first conductor track may be produced, for example, in one piece from a conductor surface of the circuit board. In one embodiment, the first conductor track is a ground surface or ground conductor.

The influences of homogeneous magnetic alternating fields on the line are compensated for by the symmetry of the conductor loops.

In one embodiment of the line, the first conductor loop has a third interruption. The third interruption is bridged by a component that has an increasing conductivity value for an increasing presence of a voltage of one and/or of both polarities. For example, the third interruption may be bridged by a diode or another component with a non-linear characteristic. In one embodiment, the third interruption may be bridged by two components that are arranged with opposing alignment or polarity in relation to one another. When a second conductor loop is provided, for this too, a third interruption may be bridged by a comparable component.

In one embodiment, the third interruption in the first conductor loop is only closed by the bridging component when the voltage present exceeds a threshold value. Thus high-frequency signals with low magnetic field strength are not influenced by the conductor loop, since the induced voltage does not exceed the threshold value. Strong excitation pulses, which also give rise to a disruptive standing wave, exceed the threshold value and will be suppressed by the standing wave trap of the line.

In one embodiment of the line, the line features a third conductor loop that is arranged at a position along the extent of the first conductor track on the carrier material. The position of the third conductor loop is at a predetermined distance from the position of the first conductor loop along the extent of the first conductor track. In one embodiment, the distance is not equal to zero, so that the first and the third conductor loop do not lie above one another covering the same area.

In one embodiment, a third conductor loop along the conductor track of the line makes it possible, even with longer lines, to suppress the formation of a standing wave.

In one embodiment of the line, a surface surrounded by the first conductor loop has a non-empty intersection with a surface surrounded by the third conductor loop. In other words, the first conductor loop and the third conductor loop overlap.

In that the first and the third conductor loop overlap, the magnetic field created by the first conductor loop in the third conductor loop in the overlapping area, for example, has a different leading sign than in the remainder of the surface surrounded by the third conductor loop. Both of the fields created by the first conductor loop, therefore, at least partly cancel each other out in effect on the third conductor loop, even entirely with a suitable choice of surface. In this way, the first conductor loop and the third conductor loop may be decoupled from each other. In one embodiment, the first conductor loop and the third conductor loop are arranged spaced apart from one another, so that a decoupling is undertaken in this way.

### BRIEF DESCRIPTION OF THE DRAWINGS

FIG. 1 shows an exemplary schematic diagram of a line with a standing wave trap;

FIG. 2 shows an exemplary schematic diagram of a line with a standing wave trap for a plurality of conductor tracks;

FIG. 3 shows a cross section along the axis A-A through one embodiment of a line;

FIG. 4 shows a cross section along the axis A-A through one embodiment of a line;

FIG. 5 shows a cross section along the axis A-A through one embodiment of a line;

FIG. 6 shows an exemplary schematic diagram of a line with a plurality of standing wave traps;

FIG. 7 shows an exemplary schematic diagram of a further line with a plurality of standing wave traps;

FIG. 8 shows an exemplary schematic diagram of a further form of embodiment of a line;

FIG. 9 shows an exemplary schematic diagram of a form of embodiment of a conductor loop of a line; and

FIG. 10 shows an exemplary schematic diagram of a further form of embodiment of a line.

### DETAILED DESCRIPTION

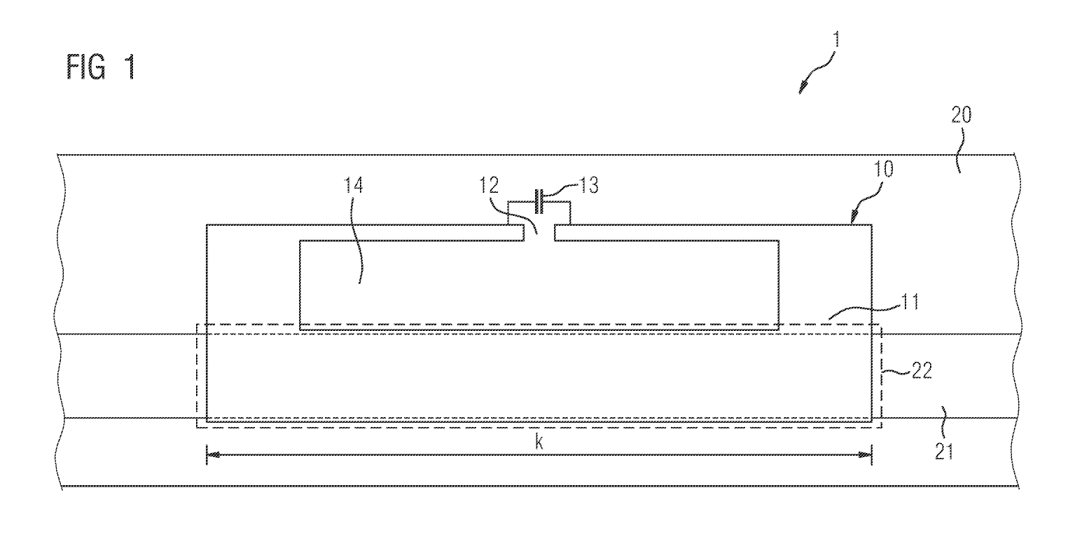

FIG. 1 shows one embodiment of a line 1 with a first standing wave trap 10 in a view from above. The line 1 has a carrier material 20 with a first conductor track 21. In this case, the carrier material 20 may be an insulator, and the conductor track 21 is made of a material with good conductivity (e.g., a metal such as copper, silver, aluminum or alloys or materials with good conductivity). The line 1 may be manufactured easily if the carrier material 20 is a circuit board, optionally flexible or rigid. In one embodiment, the carrier material 20 may surround the first conductor track 21 in a similar way to a coaxial line.

In one embodiment, a first conductor loop 11 is arranged on or in the carrier material 20. The first conductor loop 11 is ohmically or galvanically connected to the first conductor track 21. In this case, the first conductor track 21 may form a ground line or ground surface of the line 1.

In one embodiment, the first conductor loop 11 may be spaced apart from the first conductor track 21, so that no ohmic contact exists between the first conductor track 21 and the first conductor loop 11. The distance between the first conductor track 21 and the first conductor loop 11 may be provided, for example, by the carrier material being embodied flat and the first conductor track 21 and the first conductor loop 11 being located on opposite sides of the flat carrier material 20. In one embodiment, the carrier material 20 may be configured in a number of planar layers, so that an insulating layer of the carrier material 20 is arranged between first conductor track 21 and the first conductor loop 11.

An interruption 12 is made in the first conductor loop 11 so that the first conductor loop 11 embodies a coil that has connections to the first interruption 12 that are ohmically connected to one another via the first conductor loop 11. The first conductor loop 11 surrounds a first surface 14. In one embodiment, the first interruption 12 is bridged by a first capacitance 13 (e.g., a capacitor). In one embodiment, the interruption 12 may provide the first capacitance 13, given suitable dimensions and materials, by sections of the conductor loop 11 lying opposite the interruption.

The first capacitance 13 in this case, with the first conductor loop 11, which has an inductance, forms a parallel resonant circuit. Through a suitable first capacitance 13, as a function of the inductance of the first conductor loop 11, a resonant frequency of the parallel resonant circuit is able to be set, which, for example, corresponds to the Larmor frequency of a magnetic resonance tomograph. An adjustable capacitor or a combination of a fixed capacitance and an adjustable trim capacitance may be provided.

In one embodiment, the first conductor loop 11 is routed in a coupling area 22 over a predefined distance k spaced a short distance away from the first conductor track 21. The short distance in this case is given by the carrier material 20 (e.g., the thickness of the carrier material 20 or of a single layer of the carrier material 20) and is, for example, smaller than 5 mm, 1 mm or 0.1 mm. This distance is, however, large enough for the first conductor loop 11 and the first conductor track 21 to be reliably insulated from one another even for voltages that are induced by excitation pulses of the magnetic resonance tomograph. In this way, a coupling for electrical alternating currents exists between the first conductor loop 11 and the first conductor track 21, especially on a capacitive path. The conductor loop 11 thus acts as a blocking circuit for an electromagnetic wave of a frequency in the area of the resonant frequency of the parallel resonant circuit, which propagates along the first conductor track 11. The resonant frequency itself and also the width of the frequency range and the effectiveness of the standing wave trap 10, 30 are in this case dependent on the quality of the parallel resonant circuit and the coupling with the first conductor track (e.g., also the surface of the coupling area 22 or of a surface defined by the width of the first conductor track and the distance k).

In one embodiment, the first conductor loop 11 and the first conductor track 21 may be in ohmic contact (e.g., by a connecting bridge, a resistor or simply by the first conductor loop 11 and the first conductor track 21 being formed in one piece from a conductor surface of the carrier material 20). In one embodiment, the first conductor track is a ground conductor or a ground surface with a reference potential.

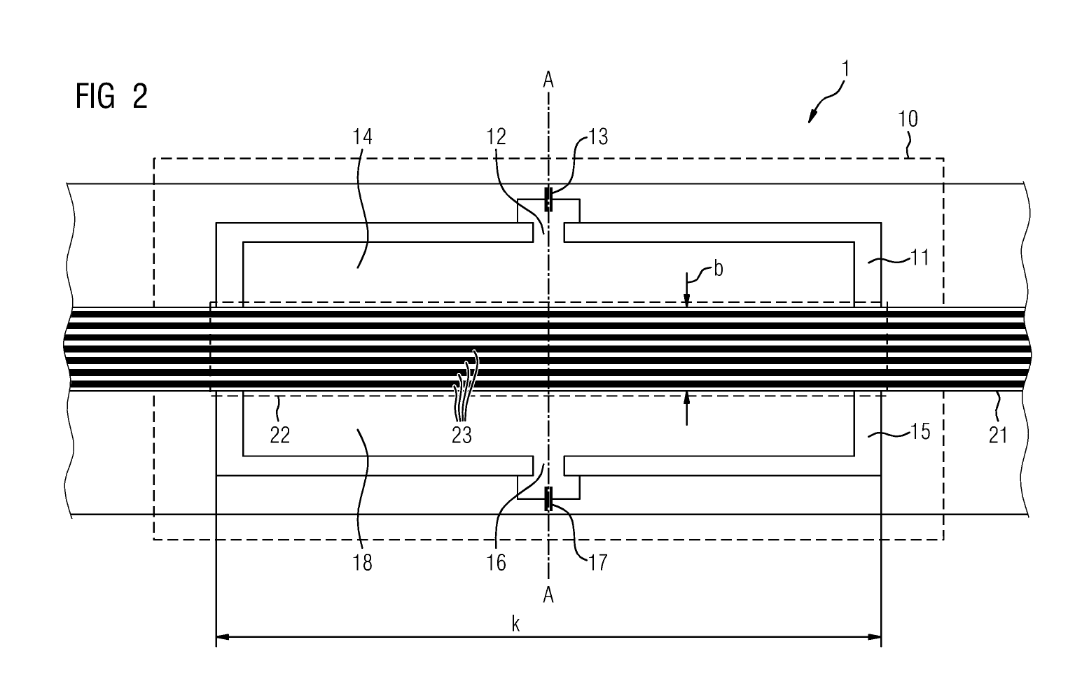

In the first conductor loop 11 shown in FIG. 1, a current is also induced by an external magnetic alternating field (e.g., caused by a radio-frequency excitation pulse of the magnetic resonance tomograph) that couples into the first conductor track 21 via the coupling area 22. Depending on the arrangement, the conductor loop may not only block a standing wave, but under unfavorable circumstances, may also give rise to an alternating voltage in the first conductor track. The form of embodiment of the line 1 shown in FIG. 2 gives one option for reducing this effect.

The line 1 of FIG. 2 differs from the form of embodiment of FIG. 1 by a second conductor loop 15 with a second interruption 16 and a second capacitance 17 being provided. The second conductor loop 15 surrounds a second surface 18 that extends in an area of the carrier material 20 that extends in an opposite direction in relation to the first conductor track 21. In other words, with a flat carrier material 20, the material is divided by the first conductor track into a first subarea and into a second subarea that are disjoint to one another. In this case, the first surface 14 essentially extends in the first subarea and the second surface 18 extends in the second subarea. The first conductor loop and the second conductor loop, in relation to the first conductor track, lie opposite the track or are adjacent to one another.

The first conductor loop 11 and the second conductor loop 15 may be galvanically connected to one another, for example by a common conductor surface in the coupling area. This common conductor surface in the coupling area may also be the first conductor track 21. The first conductor loop 11 and the second conductor loop 15 may, however, also be configured as separate conductor loops. The coupling surfaces are then arranged above and below the first conductor track 21 and are coupled capacitively and/or inductively.

If a magnetic alternating field in the dimensions of the standing wave trap 10, 30 is approximately homogeneous (e.g., when the wavelength of the electromagnetic wave is larger by a multiple than the dimensions of the standing wave trap 10, 30), then in the coupling area 22 precisely the induced currents flowing through the first conductor loop 11 and the second conductor loop 15 cancel each other out. For this purpose, the surrounded surfaces of the conductor loops may essentially be the same size (e.g., the surrounded surfaces deviate from one another only by 5, 10, 20 or 50%). In the same way, the coupling area 22 for ohmically separated first and second conductor loops 11, 15, in that the first conductor track 21 runs in parallel at a short distance from the first conductor loop 11 and the second conductor loop 15, may be essentially the same size. In other words, the values for the distance k for the two conductor loops 11, 15 deviate by only 5, 10, 20 or 50% from one another.

The line 1 shown in FIG. 2 differs from the line 1 of FIG. 1 in that the line of FIG. 2, as well as the first conductor track 21, also has a number of second conductor tracks 23, so that a number of signals may also be transmitted simultaneously and independently of one another with the line 1 of FIG. 2. As a result of the previously explained local homogeneity of the magnetic alternating field in relation to the width of the first and second conductor tracks 21, 23, the first conductor loop 11 and the second conductor loop 15, by a common coupling to a standing wave current, may block the current proportionally in the individual first and second conductor tracks 21, 23. In this way, a first standing wave trap 10 is easily able to be provided for a plurality of conductor tracks 21, 23.

In a form of embodiment with second conductor tracks 23, the first conductor track 21 is configured as a ground surface that is arranged in another layer of the circuit board essentially in parallel to the second conductor tracks 23 and separated from the second conductor tracks 23 by an insulation layer. In such cases, the first conductor track 21 may be configured in one piece with the first conductor loop 11 and the second conductor loop 15.

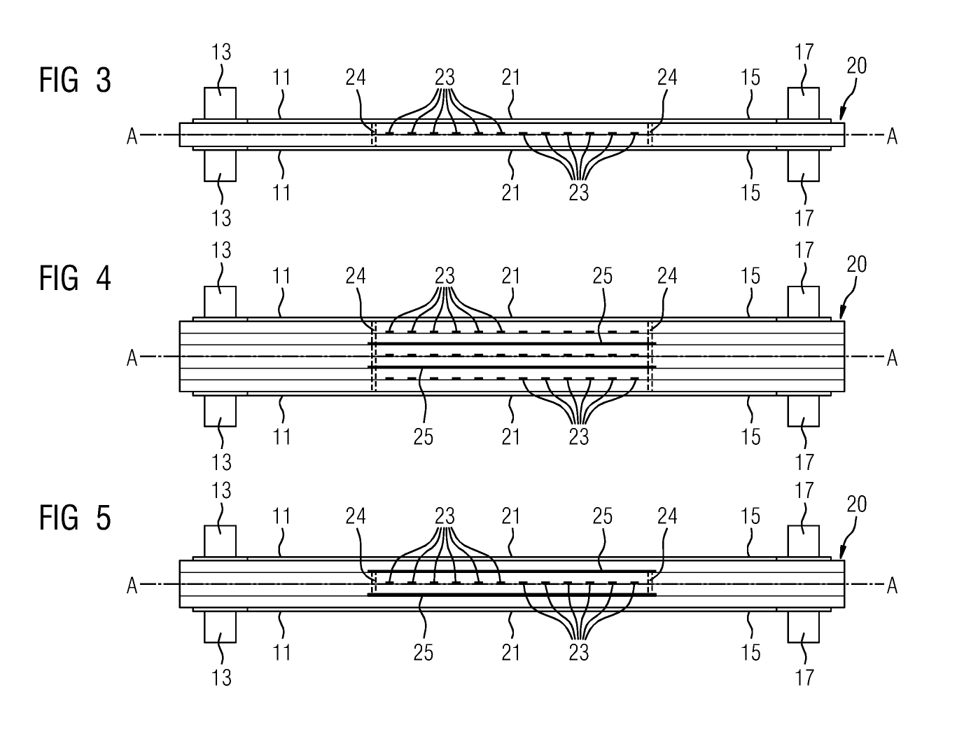

In FIGS. 3, 4 and 5, different embodiments of the line 1 are shown in cross section along the axis A-A of FIG. 2. The factor common to FIGS. 3 to 5 is that the figures specify options for how the individual first or second conductor tracks 21, 23 may be screened from one another and from the outside. The same reference characters designate the same objects, but for reasons of clarity, not all reference characters already mentioned are repeated.

For example, in FIG. 3, a 3-layer carrier material 20 is specified, in the middle of which the two conductor tracks 23 are arranged. For lateral screening, additional through-contactings 24 are provided.

Conductor tracks are arranged on both surfaces (in FIG. 3 upper or lower) of the carrier material 20, on which in each case a first conductor track 21, a first conductor loop 11, and a second conductor loop 15 are arranged. The first conductor tracks 21 are configured as ground conductors and are connected to one another by through-contacting 24, so that the second conductor tracks 23, which serve as signal lines, are screened from all sides.

FIG. 4 shows a carrier material with seven planes for conductive material, so that in each case, ground surfaces 25 for screening out mutual influences of second conductor tracks 23 on one another are provided between planes with first or second conductor tracks.

In FIG. 5, the second conductor tracks 23 are surrounded by ground surfaces 25 and through-contactings 24 and are screened from the outside independently of the first conductor tracks 21.

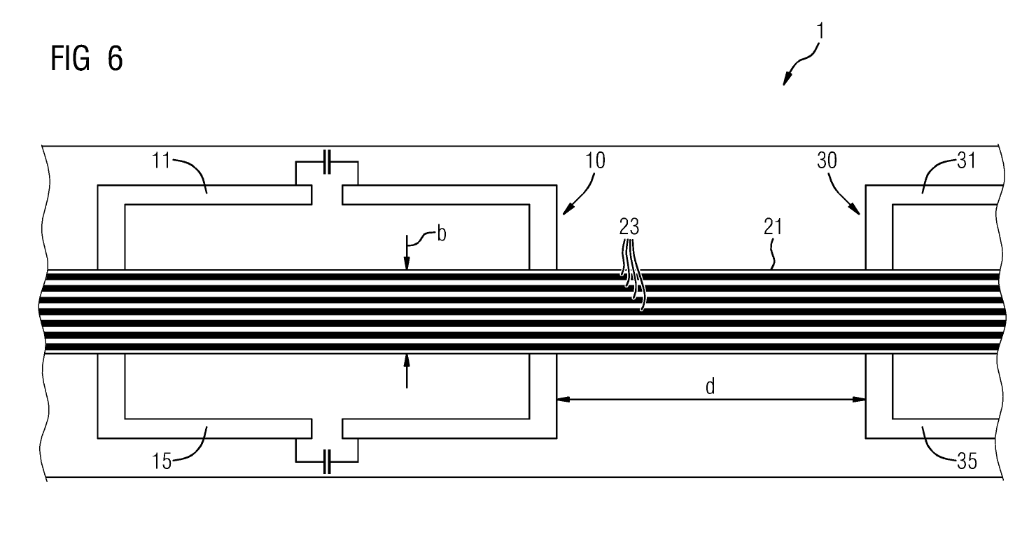

Standing wave traps 10, 30 are, as shown in FIG. 6, arranged repeatedly along the line 1 in order, for lines with a length of the order of magnitude of the wavelength of the standing waves to be suppressed, to provide sufficient protection. However, the smaller the distance d between two standing wave traps 10, 30 or corresponding conductor loops 11, 15 and 31, 35 along the extent of the line 1, the more strongly two adjacent conductor loops 11, 31 or 15, 35 interact with one another as a result of the electromagnetic alternating fields created by the two adjacent conductor loops 11, 31 or 15, 35.

A decoupling in this case is be achieved, as shown in FIG. 6, by the distance d being selected sufficiently large, but which, as previously explained, reduces the effect as standing wave trap.

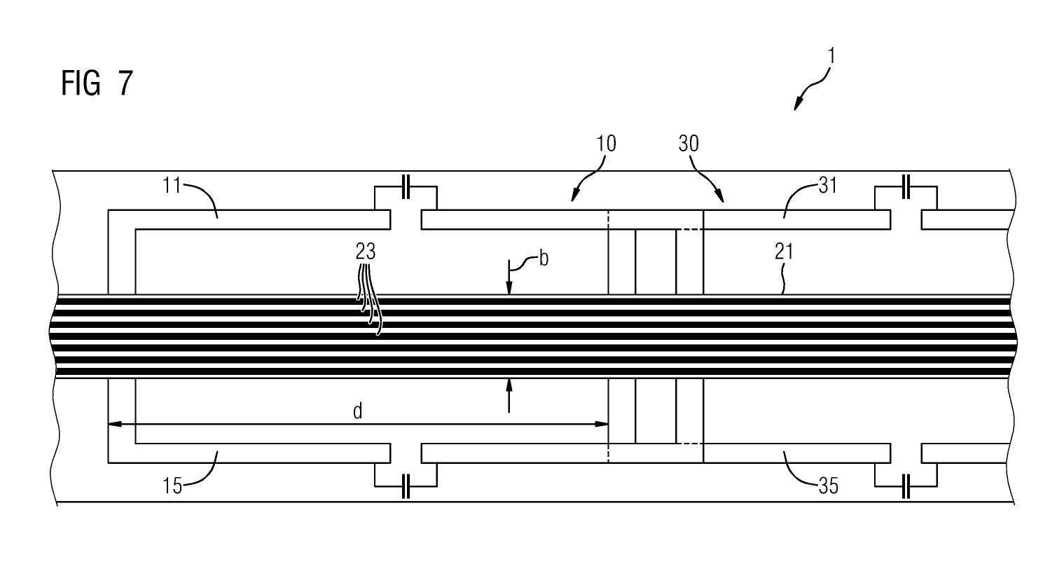

FIG. 7 shows another option for mutual decoupling of standing wave traps 10, 30. In the form of embodiment shown in FIG. 7, a first standing wave trap 10 and a second standing wave trap 30 are arranged along the line 1 such that corresponding conductor loops 11, 31 or 15, 35 overlap with each other. In this case, the surface surrounded by the first conductor loop 11 has a non-empty intersection with a surface surrounded by the third conductor loop 31; likewise, the surface surrounded by the second conductor loop 15 has a non-empty intersection with a surface surrounded by the fourth conductor loop 35. Since the magnetic field created by a conductor loop changes the polarity between surrounded surface and a surface lying outside, with a suitable choice of intersection of the surfaces, the effect of the adjacent conductor loop is just canceled out.

In one embodiment, the principles of decoupling presented may also be applied to a line of FIG. 1. For example, in a line 1 of FIG. 1, which has a first conductor loop 11 only on one side of the first conductor track, a second standing wave trap 30 with a third conductor loop 31 on the same side of the conductor track 1 may be decoupled, in that a sufficient distance d between the conductor loops 11, 31 is provided or a suitable overlap is provided by the surfaces surrounded by the first conductor loop 11 and the third conductor loop 31.

The overlap may, for example, be realized by the conductor loops 11, 15, 31, 35 being arranged in different layers of the carrier material and separated galvanically from one another in this way.

In magnetic resonance tomography, both the excitation of the nuclear spin and also the emission of the measurement signal occur at the Larmor frequency. The standing wave trap 10, 30 is intended to suppress the formation of a standing wave by the excitation signal with high field strength but not to influence the receipt of the weak measurement signal if possible.

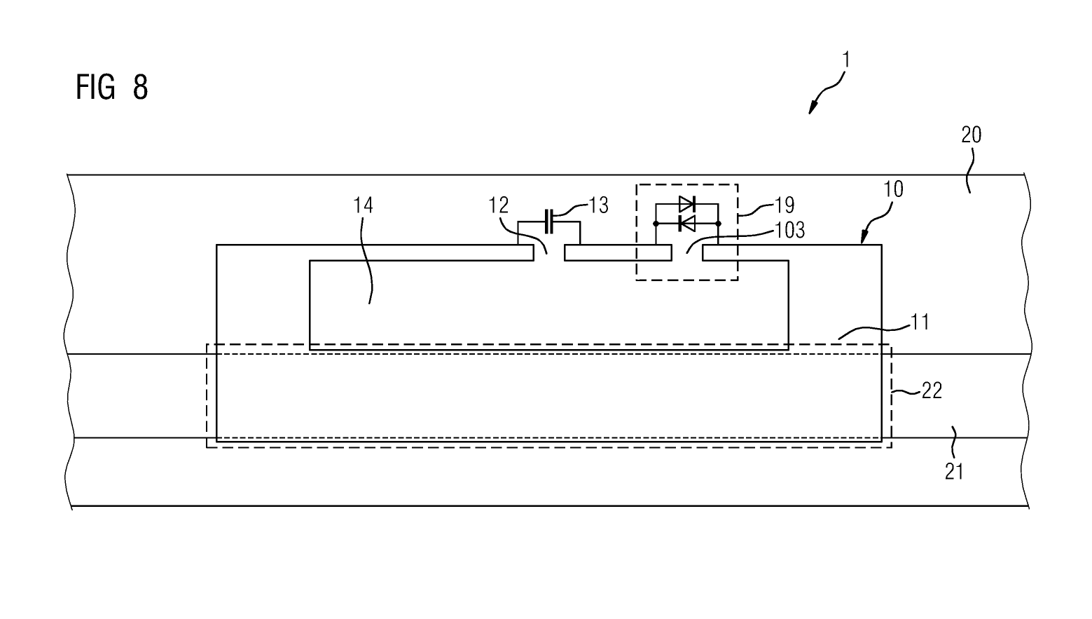

FIG. 8 shows a possible embodiment of a line in which this is realized. The same elements are provided with the same reference characters.

The standing wave trap 10 of the line 1 in FIG. 8 has a third interruption 103 of the first conductor loop 11, which is bridged by a non-linear component 19. The non-linear component 19 may have a higher conductivity value if a higher voltage is present. The non-linear component 19 may, for example, feature a diode, two anti-parallel switched diodes, a Zener diode, or another component with a corresponding non-linear characteristic.

If an excitation field is created with high magnetic field strength, then a high voltage is induced in the first conductor loop 11. The non-linear component 19 then has a high conductivity value, and the first conductor loop 11 may be effective as the parallel resonant circuit. In the case of the receipt of the resonant signal, however, as a result of the low field strength, the induced voltage is so small that the non-linear component essentially does not conduct and the parallel resonant circuit is interrupted, so that parallel resonant circuit influences the resonant signal at the Larmor frequency only slightly. In one embodiment, the non-linear component 19 may be explicitly switched by a control voltage applied from outside.

The non-linear component may be provided in all conductor loops 11, 15, 31, 35 of the forms of embodiment shown in FIGS. 1 to 7.

In a magnetic resonance tomograph, strong magnetic alternating fields with lower frequency than gradient fields will also be created for spatial encoding. The gradient fields create eddy currents in larger metal surfaces, as are represented, for example, by the conductor loops 11, 15, 31, 35 in the coupling area (e.g., when a plurality of second conductor tracks 23 next to one another is provided).

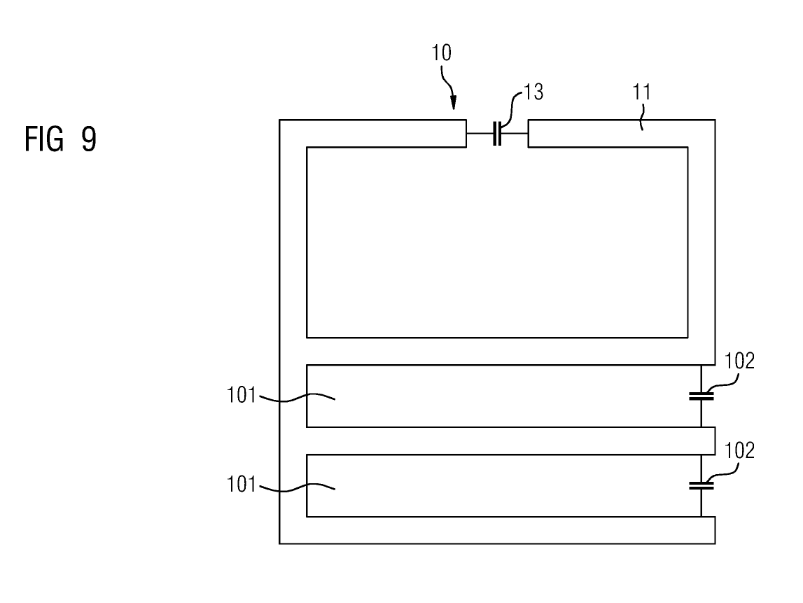

A possible solution is shown in FIG. 9, which specifies a form of embodiment for a conductor loop 11, 15, 31, 35 of a line 1. The same objects are labeled with the same reference characters.

In FIG. 9, the conductor loop 11 in the wide coupling area 22 has a number of slots 101, at which the conductor surface of the conductor loop 11 is removed. The slots may extend in the direction of extent of the first or second conductor tracks 21, 23. Since the gradient pulses usually lie in a frequency range below 100 kHz, while the excitation pulses have the Larmor frequency with values greater than 1 MHz, the slots may be short circuited for radio-frequency currents with the Larmor frequency by bridging capacitances 102 for signals with the Larmor frequency, without simultaneously significantly reducing the interrupting effect for eddy currents created by gradient fields.

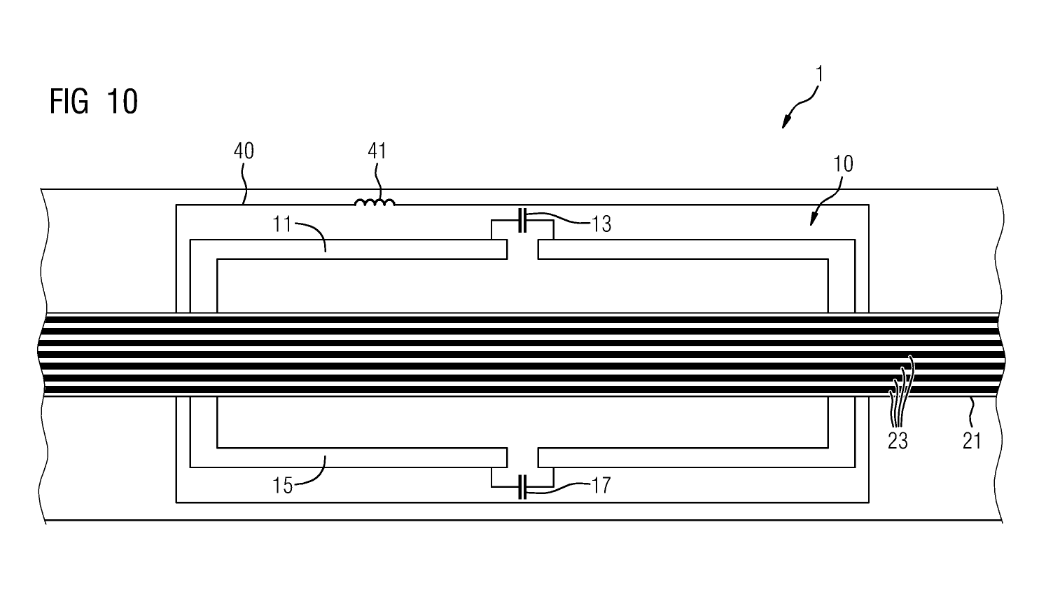

The standing wave traps shown in FIGS. 2, 6 and 7 with first conductor loop 11 and second conductor loop 15 on both sides of the first conductor track 21 tend, in addition, to also form higher-frequency loop modes as well as a desired resonance mode, in which the currents induced directly in the two conductor loops compensate for each other. To suppress these loop modes, as shown in FIG. 10, a ring loop 40 may be used.

The ring loop 40 surrounds the first conductor loop 11 and the second conductor loop 15 at a small distance around the outer circumference. The ring loop 40 may also have an interruption that is bridged by the tuning inductance 41.

Although the invention has been illustrated and described in greater detail by the exemplary embodiments, the invention is not, however, restricted by the disclosed examples. Other variations may be derived herefrom by the person skilled in the art without departing from the scope of protection of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A line with a standing wave trap for a magnetic resonance tomograph, the line comprising:
a carrier material;
a first conductor track that extends along the carrier material in the carrier material or on the carrier material; and
a first conductor loop that is arranged on or in the carrier material,
wherein the first conductor loop has a signal coupling to the first conductor track, and
wherein the first conductor loop has a first interruption that is bridged with a first capacitance.

2. The line of claim 1, wherein the carrier material is a circuit board.

3. The line of claim 1, wherein the first conductor loop is in ohmic contact in a coupling area with the first conductor track.

4. The line of claim 1, wherein the first conductor loop is routed in a coupling area over a prespecified distance spaced at a distance from the first conductor track to achieve the signal coupling.

5. The line of claim 3, wherein the carrier material has one or more second conductor tracks, the one or more second conductor tracks having a signal coupling to the first conductor loop.

6. The line of claim 5, wherein the first conductor loop has a slot in the coupling area, the slot not interrupting the first conductor loop.

7. The line of claim 6, wherein the first conductor loop has a bridging capacitance that bridges the slot.

8. The line as claimed of claim 1, wherein the standing wave trap includes a second conductor loop that has a signal coupling to the first conductor track,
wherein the carrier material has a planar shape and is divided by the first conductor track into a first subsurface and a second, disjoint subsurface, and the first conductor loop essentially extends in the first subarea and the second conductor loop essentially extends in the second subarea.

9. The line as claimed of claim 1, wherein the first conductor loop has a second interruption,
wherein the second interruption is bridged by a non-linear component that, with increasing presence of a voltage of one, both, or the one and both polarities, has an increasing conductivity value.

10. The line of claim 1, further comprising a second conductor loop that at a position along the extent of the first conductor track is arranged on the carrier material, which is at a prespecified distance from the position of the first conductor loop along the extent of the first conductor track.

11. The line of claim 9, wherein a surface surrounded by the first conductor loop has a non-empty intersection with a surface surrounded by the second conductor loop.

12. A patient couch for a magnetic resonance tomograph, the patient couch comprising:
a line with a standing wave trap for a magnetic resonance tomograph, the line comprising:
a carrier material;
a first conductor track that extends along the carrier material in the carrier material or on the carrier material; and
a first conductor loop that is arranged on or in the carrier material,
wherein the first conductor loop has a signal coupling to the first conductor track, and
wherein the first conductor loop has a first interruption that is bridged with a first capacitance.

13. The patient couch of claim 12, wherein the carrier material is a circuit board.

14. The patient couch of claim 12, wherein the first conductor loop is in ohmic contact in a coupling area with the first conductor track.

15. The patient couch of claim 12, wherein the first conductor loop is routed in a coupling area over a prespecified distance spaced at a distance from the first conductor track to achieve the signal coupling.

16. A magnetic resonance tomograph comprising:
a line with a standing wave trap for a magnetic resonance tomograph, the line comprising:
a carrier material;
a first conductor track that extends along the carrier material in the carrier material or on the carrier material; and
a first conductor loop that is arranged on or in the carrier material,
wherein the first conductor loop has a signal coupling to the first conductor track, and
wherein the first conductor loop has a first interruption that is bridged with a first capacitance.

17. The magnetic resonance tomograph of claim 16, wherein the carrier material is a circuit board.

18. The magnetic resonance tomograph of claim 16, wherein the first conductor loop is in ohmic contact in a coupling area with the first conductor track.

19. The magnetic resonance tomograph of claim 16, wherein the first conductor loop is routed in a coupling area over a prespecified distance spaced at a distance from the first conductor track to achieve the signal coupling.
